(19) United States
(12) Patent Application Publication
(10) Pub. No.: US 2024/0096776 A1
(43) Pub. Date: Mar. 21, 2024

(54) PACKAGE SUBSTRATE

(71) Applicant: AaltoSemi Inc., Nanjing City (CN)

(72) Inventors: Andrew C. CHANG, Nanjing City (CN); Min-Yao CHEN, Nanjing City (CN); Sung-Kun LIN, Nanjing City (CN)

(21) Appl. No.: 18/240,592

(22) Filed: Aug. 31, 2023

(30) Foreign Application Priority Data
Sep. 19, 2022 (TW) 111135392

(51) Int. Cl. H01L 23/498

(52) U.S. Cl. CPC H01L 23/49838; H01L 23/49822; H01L 23/49827; H01L 23/49894

(57) ABSTRACT

A package substrate is provided and includes a core board body and a first circuit structure and a second circuit structure disposed on opposite sides of the core board body, where the number of wiring layers of the second circuit structure is different from the number of wiring layers of the first circuit structure, so that the package substrate is asymmetrical. The first circuit structure and the second circuit structure are designed according to the thickness and coefficient of thermal expansion of the first dielectric layer of the first circuit structure and the second dielectric layer of the second circuit structure, so as to prevent the problem of warping from occurring to the package substrate.

### BACKGROUND

### 1. Technical Field

The present disclosure relates to a package substrate for semiconductor manufacturing process, and more particularly, to an asymmetric package substrate.

### 2. Description of Related Art

With the development of industrial applications, in recent years, it has gradually developed toward 5G high-frequency communication, augmented reality (AR), virtual reality (VR), and the like. Therefore, it is more necessary to develop high-end semiconductor packaging technology to be applied to semiconductor flip-chip packaging or multi-chip packaging such as artificial intelligence (AI) chips, high-end chips, and multi-chips. Under this packaging requirement, the package size is bound to become larger and the number of stacked layers is also higher and higher, which leads to the circuit design in the direction of high density, fine line spacing, and high number of electrical connection points, so as to meet the packaging requirements of the aforementioned chips.

FIG. 1A is a cross-sectional view of a conventional package substrate 1. As shown in FIG. 1A, the package substrate 1 includes a core board body 10 having a first side 10a and a second side 10b opposing the first side 10a, and a first circuit structure 11 is formed on the first side 10a of the core board body 10, and a second circuit structure 12 is formed on the second side 10b of the core board body 10, wherein the core board body 10 has a plurality of conductive vias 100 communicating with the first side 10a and the second side 10b to electrically connect the first circuit structure 11 and the second circuit structure 12, and the number of wiring layers of the first circuit structure 11 and the number of wiring layers of the second circuit structure 12 are the same, so that the package substrate 1 is symmetrical based on the number of wiring layers, and wherein one of the first circuit structure 11 and the second circuit structure 12 is served as a chip-placing side for placing a semiconductor chip, while the other one of the first circuit structure 11 and the second circuit structure 12 is served as a mounting side for mounting a circuit board.

However, in the conventional package substrate 1, there are many contacts on the chip-placing side, and few contacts on the mounting side. If the number of wiring layers of the first circuit structure 11 and the number of wiring layers of the second circuit structure 12 are designed to be the same, then the circuit structure on the mounting side is not only difficult to layout, but also its manufacturing cost is obviously too much, resulting in poor manufacturing efficiency of the package substrate 1 and difficulty in reducing manufacturing cost.

Furthermore, although the manufacturing cost can be reduced by reducing the number of wiring layers on the mounting side (such as the second circuit structure 12 shown in FIG. 1B), when the number of wiring layers of the first circuit structure 11 and the number of wiring layers of the second circuit structure 12 are different, the coefficient of thermal expansion (CTE) of the overall circuit structure on the first side 10a and the CTE of the overall circuit structure on the second side 10b of the package substrate 1 are different due to the asymmetry of the wiring layers on the first side 10a and the second side 10b of the package substrate 1, resulting in warping of the package substrate 1.

Therefore, how to overcome various problems of the above-mentioned prior art has become a problem urgently to be solved.

### SUMMARY

In view of the above-mentioned deficiencies in the prior art, the present disclosure provides a package substrate, which comprises: a core board body being defined with a first side and a second side opposing the first side, wherein the core board body has a plurality of conductive vias communicating with the first side and the second side; a first circuit structure disposed on the first side of the core board body, wherein the first circuit structure includes at least one first dielectric layer and a first circuit layer bonded to the first dielectric layer and electrically connected to the conductive vias; and a second circuit structure disposed on the second side of the core board body, wherein the second circuit structure includes at least one second dielectric layer and a second circuit layer bonded to the second dielectric layer and electrically connected to the conductive vias, wherein a number of wiring layers of the first circuit structure is different from a number of wiring layers of the second circuit structure, so that the package substrate is asymmetrical based on the number of the wiring layers of the first circuit structure and the number of the wiring layers of the second circuit structure, and a configuration of the package substrate satisfies a target formula:

$${L}^{2} \frac{3 {( 1 + {P}_{1} )}^{2} ( {a}_{2} - {a}_{1} ) ( T - {T}_{0} )}{4 {T}_{1} [ 3 {( 1 + {P}_{1} )}^{2} + ( 1 + {P}_{1} {M}_{1} ) ( {{P}_{1}}^{2} + 1 / {P}_{1} {M}_{1} ) ]} = {L}^{2} \frac{3 {( 1 + {P}_{2} )}^{2} ( {a}_{2} - {a}_{3} ) ( T - {T}_{0} )}{4 {T}_{2} [ 3 {( 1 + {P}_{2} )}^{2} + ( 1 + {P}_{2} {M}_{2} ) ( {{P}_{2}}^{2} + 1 / {P}_{2} {M}_{2} ) ]}$$

wherein L=a length of the package substrate; T−T₀=a processing temperature; a₁=a coefficient of thermal expansion of the first dielectric layer; a₂=a coefficient of thermal expansion of the core board body; a₃=a coefficient of thermal expansion of the second dielectric layer; T₁=t₁+t₂; M₁=E₁/E₂; P₁=t₁/t₂; T₂=t₃+t₂; M₂=E₃/E₂; P₂=t₃/t₂; t₁=an overall thickness of the first dielectric layer; t₂=a thickness of the core board body; t₃=an overall thickness of the second dielectric layer; E₁=a Young's modulus of the first circuit structure; E₂=a Young's modulus of the core board body; and E₃=a Young's modulus of the second circuit structure.

In the aforementioned package substrate, the core board body has a first inner circuit layer formed on the first side of the core board body and a second inner circuit layer formed on the second side of the core board body, so that the conductive vias are electrically connected to the first inner circuit layer and the second inner circuit layer.

In the aforementioned package substrate, the number of the wiring layers of the first circuit structure is greater than the number of the wiring layers of the second circuit structure. For example, the coefficient of thermal expansion of the second dielectric layer is greater than or equal to the coefficient of thermal expansion of the first dielectric layer. Alternatively, a single-layer thickness of the second dielectric layer is greater than or equal to a single-layer thickness of the first dielectric layer.

In the aforementioned package substrate, a material for forming the first dielectric layer is Ajinomoto build-up film, prepreg, or bismaleimide triazine material.

In the aforementioned package substrate, a material for forming the second dielectric layer is Ajinomoto build-up film, prepreg, or bismaleimide triazine material.

In the aforementioned package substrate, a material of the first dielectric layer and a material of the second dielectric layer are the same.

In the aforementioned package substrate, a material of the first dielectric layer and a material of the second dielectric layer are different.

In the aforementioned package substrate, the target formula is based on a Timoshenko's bending formula as a calculation basis.

It can be seen from the above that in the package substrate of the present disclosure, the first circuit structure and the second circuit structure are configured via the target formula to design an asymmetric package substrate that will not warp. Therefore, compared with the prior art, the package substrate of the present disclosure is not only easy to layout the circuit structure on the mounting side, but also can reduce the manufacturing cost of the circuit structure on the mounting side, so as to reduce the manufacturing cost of the package substrate.

### BRIEF DESCRIPTION OF THE DRAWINGS

FIG. 1A is a cross-sectional view of a conventional symmetrical package substrate.

FIG. 1B is a cross-sectional view of a conventional asymmetric package substrate.

FIG. 2 is a schematic cross-sectional view of a package substrate according to the present disclosure.

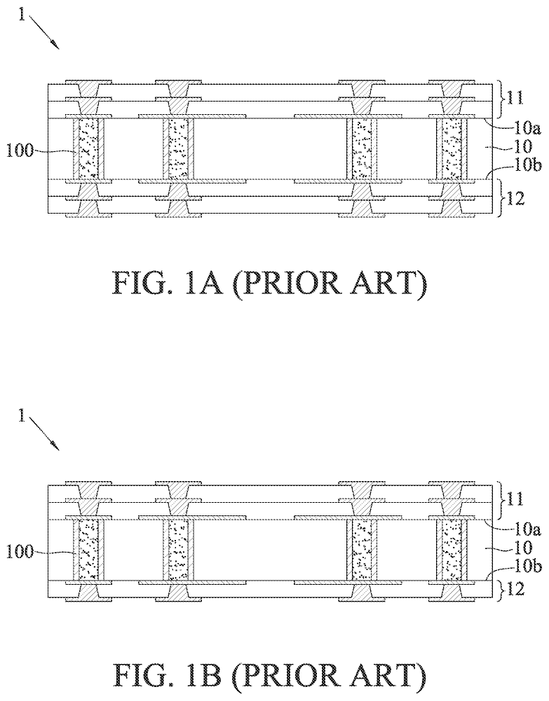

### DETAILED DESCRIPTION

The following describes the implementation of the present disclosure with examples. Those skilled in the art can easily understand other advantages and effects of the present disclosure from the content disclosed in this specification.

It should be understood that, the structures, ratios, sizes, and the like in the accompanying figures are used for illustrative purposes to facilitate the perusal and comprehension of the content disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical content disclosed in the present specification. Meanwhile, terms such as “on,” “upper,” “below,” “lower,” “first,” “second,” “a,” “one” and the like are merely used for clear explanation rather than limiting the practicable scope of the present disclosure, and thus, alterations or adjustments of the relative relationships thereof without essentially altering the technical content should still be considered in the practicable scope of the present disclosure.

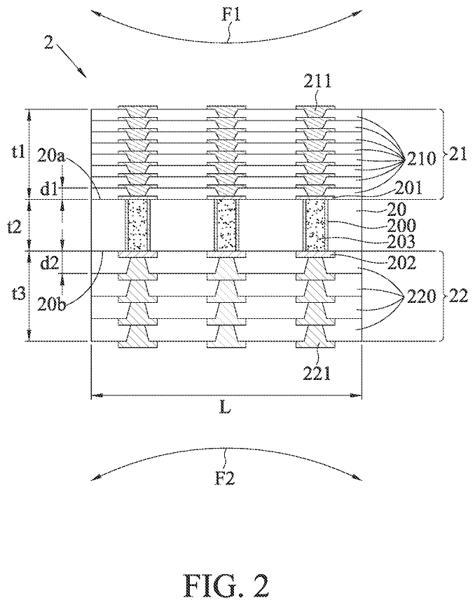

FIG. 2 is a schematic cross-sectional view of a package substrate 2 according to the present disclosure. In an embodiment, the package substrate 2 is used to carry a semiconductor chip.

As shown in FIG. 2, the package substrate 2 includes: a core board body 20 defined with a first side 20a (such as the upper side) and a second side 20b (such as the lower side) opposing the first side 20a, a first circuit structure 21 disposed on the first side 20a of the core board body 20, and a second circuit structure 22 disposed on the second side 20b of the core board body 20.

The core board body 20 has a plurality of conductive vias 200 communicating with the first side 20a and the second side 20b.

In an embodiment, the core board body 20 is of a single core layer specification, and a first inner circuit layer 201 and a second inner circuit layer 202 are formed on the first side 20a and the second side 20b respectively, so that the plurality of conductive vias 200 are electrically connected to the first inner circuit layer 201 and the second inner circuit layer 202.

Moreover, each of the conductive vias 200 is a hollow column, which can be filled with a plugging material 203 in the hollow, wherein the plugging material 203 has various types, such as conductive glue, ink, etc., and is not particularly limited. It should be understood that, in other embodiments, the conductive via 200 may also be a solid metal cylinder without filling the plugging material 203.

The first circuit structure 21 includes at least one first dielectric layer 210 and a first circuit layer 211 bonded to the first dielectric layer 210 and electrically connected to the conductive via 200.

The second circuit structure 22 includes at least one second dielectric layer 220 and a second circuit layer 221 bonded to the second dielectric layer 220 and electrically connected to the conductive via 200, wherein the number of wiring layers of the first circuit structure 21 is different from the number of wiring layers of the second circuit structure 22, so that the package substrate 2 is asymmetrical based on the number of wiring layers (e.g., the package substrate 2 is asymmetrical based on the number of the wiring layers of the first circuit structure 21 and the number of the wiring layers of the second circuit structure 22), and the configuration of the package substrate 2 satisfies the following target formula used to indicate the degree of warpage:

$${L}^{2} \frac{3 {( 1 + {P}_{1} )}^{2} ( {a}_{2} - {a}_{1} ) ( T - {T}_{0} )}{4 {T}_{1} [ 3 {( 1 + {P}_{1} )}^{2} + ( 1 + {P}_{1} {M}_{1} ) ( {{P}_{1}}^{2} + 1 / {P}_{1} {M}_{1} ) ]} = {L}^{2} \frac{3 {( 1 + {P}_{2} )}^{2} ( {a}_{2} - {a}_{3} ) ( T - {T}_{0} )}{4 {T}_{2} [ 3 {( 1 + {P}_{2} )}^{2} + ( 1 + {P}_{2} {M}_{2} ) ( {{P}_{2}}^{2} + 1 / {P}_{2} {M}_{2} ) ]}$$

wherein the left formula represents the warping degree of the core board body 20 and the first circuit structure 21 on the first side 20a of the core board body 20, and the right formula represents the warping degree of the core board body 20 and the second circuit structure 22 on the second side 20b of the core board body 20, and
L=the length of the package substrate 2;
T−T₀=processing temperature;
a₁=CTE of the first dielectric layer 210;
a₂=CTE of the core board body 20;
a₃=CTE of the second dielectric layer 220;
T₁=t₁+t₂;
M₁=E₁/E₂;
P₁=t₁/t₂;
T₂=t₃+t₂;
M₂=E₃/E₂;
P₂=t₃/t₂;
t₁=the overall thickness of the first dielectric layer 210;
t₂=the thickness of the core board body 20;
t₃=the overall thickness of the second dielectric layer 220;
E₁=Young's modulus of the first circuit structure 21;
E₂=Young's modulus of the core board body 20; and
E₃=Young's modulus of the second circuit structure 22.

In an embodiment, the target formula is based on Timoshenko's bending formula as the calculation basis.

Moreover, the number of wiring layers (e.g., eight layers of the first dielectric layer 210 and the first circuit layer 211) of the first circuit structure 21 is greater than the number of wiring layers (e.g., four layers of the first dielectric layer 210 and the first circuit layer 211) of the second circuit structure 22, so that the first circuit structure 21 on the first side 20a is served as the chip-placing side for placing the semiconductor chip, and the second circuit structure 22 on the second side 20b is served as the mounting side for mounting the circuit board. Further, a single-layer thickness d2 of the second dielectric layer 220 is greater than or equal to a single-layer thickness d1 of the first dielectric layer 210. Alternatively, the CTE of the second dielectric layer 220 is greater than or equal to the CTE of the first dielectric layer 210.

Also, the core board body 20 contains glass fiber, such as bismaleimide triazine (BT) material or FR-5 (flame resistant/retardant 5) material, and the material for forming the first dielectric layer 210 and the second dielectric layer 220 is Ajinomoto build-up film (ABF), prepreg (PP), BT material, or other dielectric materials. It should be understood that the material of the first dielectric layer 210 and the material of the second dielectric layer 220 may be the same or different.

Therefore, the package substrate 2 according to the present disclosure is designed in such a way that the number of wiring layers of the first circuit structure 21 is different from the number of wiring layers of the second circuit structure 22, so that the second circuit structure 22 with fewer wiring layers is served as the mounting side for mounting the circuit board. Accordingly, it is not only easy to layout the circuit structure on the mounting side, but also can reduce the manufacturing cost of the circuit structure on the mounting side. Therefore, compared with the prior art, the package substrate 2 can effectively improve the manufacturing efficiency and reduce the manufacturing cost.

Moreover, the package substrate 2 according to the present disclosure also satisfies the target formula when the package substrate 2 is asymmetrical based on the number of wiring layers by the single-layer thickness d1, d2 (or overall thickness t1, t3) and CTE design of the dielectric layer. Therefore, compared with the prior art, in the package substrate 2 according to the present disclosure, even if the number of wiring layers of the first circuit structure 21 and the number of wiring layers of the second circuit structure 22 are different, the stress distribution of the overall structure on the first side 20a and the second side 20b of the package substrate 2 can still maintain the required balance, so that the package substrate 2 can effectively avoid the problem of warping.

For example, in FIG. 2, the number of wiring layers of the package substrate 2 is configured as eight layers of the first circuit layer 211 and four layers of the second circuit layer 221, wherein assuming that the processing temperature (T−T₀) is the same, the length L of the package substrate 2 is a constant value, the thickness t₂ of the core board body 20 is 800 microns (μm), and the CTE of the core board body 20 is 10, etc., so when the single-layer thickness d1 of the first dielectric layer 210 is 30 microns (overall thickness t1=30×8) and the CTE of the first dielectric layer 210 is 20, then the design of the second dielectric layer 220 can be shown in Table 1.

TABLE 1

| Single-layer thickness d2 (μm) | Overall thickness t3 (μm) | CTE |
|---|---|---|
| 60 | 60 × 4 | 20 |
| 45 | 45 × 4 | 22 |
| 30 | 30 × 4 | 26.4 |

So that the warping degree of the core board body 20 and the first circuit structure 21 on the first side 20a of the core board body 20 is equal to the warping degree of the core board body 20 and the second circuit structure 22 on the second side 20b of the core board body 20, and a warping direction F1 of the core board body 20 and the first circuit structure 21 on the first side 20a of the core board body 20 is opposite to a warping direction F2 of the core board body 20 and the second circuit structure 22 on the second side 20b of the core board body 20, so the upward warping and downward warping of the package substrate 2 cancel each other out.

Therefore, the warping degree of the package substrate 2 is mainly from (1+P1)²(α₂−α₁) or (1+P2)²(α₂−α₃), that is, the thickness ratio and CTE difference, and the influence of Young's modulus is second (i.e., the denominator of the target formula). In addition, if the processing temperature of the side with more layers (such as the first circuit structure 21) is lowered, so that the processing temperatures of the left and right expressions of the target formula are different, it will also have a slight impact, but not as much as the influence of thickness ratio, CTE difference and Young's modulus.

Furthermore, since the first circuit structure 21 has more wiring layers, the second circuit structure 22 can use a dielectric material with the thicker single-layer thickness d2 and/or a larger CTE to form the second dielectric layer 220. Therefore, when forming the first dielectric layer 210 and the second dielectric layer 220, conditions such as the single-layer thickness d1, d2 and CTE should be considered together, so as to facilitate the selection of dielectric materials suitable for manufacturing the required overall thickness t1, t3 and CTE.

To sum up, in the package substrate of the present disclosure, the first circuit structure and the second circuit structure are configured via the target formula, which can not only reduce the manufacturing cost of the circuit structure on the mounting side to reduce the manufacturing cost of the package substrate, but also prevent the problem of warping from occurring to the package substrate. Therefore, the package substrate of the present disclosure can maintain the reliability of the structure, thus effectively improving the yield rate of subsequent electronic products.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A package substrate, comprising:
a core board body being defined with a first side and a second side opposing the first side, wherein the core board body has a plurality of conductive vias communicating with the first side and the second side;
a first circuit structure disposed on the first side of the core board body, wherein the first circuit structure includes at least one first dielectric layer and a first circuit layer bonded to the first dielectric layer and electrically connected to the conductive vias; and
a second circuit structure disposed on the second side of the core board body, wherein the second circuit structure includes at least one second dielectric layer and a second circuit layer bonded to the second dielectric layer and electrically connected to the conductive vias,
wherein a number of wiring layers of the first circuit structure is different from a number of wiring layers of the second circuit structure, so that the package substrate is asymmetrical based on the number of the wiring layers of the first circuit structure and the number of the wiring layers of the second circuit structure, and a configuration of the package substrate satisfies a target formula:
$${L}^{2} \frac{3 {( 1 + {P}_{1} )}^{2} ( {a}_{2} - {a}_{1} ) ( T - {T}_{0} )}{4 {T}_{1} [ 3 {( 1 + {P}_{1} )}^{2} + ( 1 + {P}_{1} {M}_{1} ) ( {{P}_{1}}^{2} + 1 / {P}_{1} {M}_{1} ) ]} = {L}^{2} \frac{3 {( 1 + {P}_{2} )}^{2} ( {a}_{2} - {a}_{3} ) ( T - {T}_{0} )}{4 {T}_{2} [ 3 {( 1 + {P}_{2} )}^{2} + ( 1 + {P}_{2} {M}_{2} ) ( {{P}_{2}}^{2} + 1 / {P}_{2} {M}_{2} ) ]}$$
wherein L=a length of the package substrate, T−T₀=a processing temperature, a₁=a coefficient of thermal expansion of the first dielectric layer, a₂=a coefficient of thermal expansion of the core board body, a₃=a coefficient of thermal expansion of the second dielectric layer,
T₁=t₁+t₂, M₁=E₁/E₂, P₁=t₁/t₂,
T₂=t₃+t₂, M₂=E₃/E₂, P₂=t₃/t₂;
t₁=an overall thickness of the first dielectric layer, t₂=a thickness of the core board body,
t₃=an overall thickness of the second dielectric layer,
E₁=a Young's modulus of the first circuit structure, E₂=a Young's modulus of the core board body, and
E₃=a Young's modulus of the second circuit structure.

2. The package substrate of claim 1, wherein the core board body has a first inner circuit layer formed on the first side of the core board body and a second inner circuit layer formed on the second side of the core board body, so that the conductive vias are electrically connected to the first inner circuit layer and the second inner circuit layer.

3. The package substrate of claim 1, wherein the number of the wiring layers of the first circuit structure is greater than the number of the wiring layers of the second circuit structure.

4. The package substrate of claim 3, wherein the coefficient of thermal expansion of the second dielectric layer is greater than or equal to the coefficient of thermal expansion of the first dielectric layer.

5. The package substrate of claim 3, wherein a single-layer thickness of the second dielectric layer is greater than or equal to a single-layer thickness of the first dielectric layer.

6. The package substrate of claim 1, wherein a material for forming the first dielectric layer is Ajinomoto build-up film, prepreg, or bismaleimide triazine material.

7. The package substrate of claim 1, wherein a material for forming the second dielectric layer is Ajinomoto build-up film, prepreg, or bismaleimide triazine material.

8. The package substrate of claim 1, wherein a material of the first dielectric layer and a material of the second dielectric layer are the same.

9. The package substrate of claim 1, wherein a material of the first dielectric layer and a material of the second dielectric layer are different.

10. The package substrate of claim 1, wherein the target formula is based on a Timoshenko's bending formula as a calculation basis.
